(19) United States
(12) Patent Application Publication
(10) Pub. No.: US 2026/0338857 A1
(43) Pub. Date: Oct. 29, 2026

(54) TEST DEVICE TRANSPORT SYSTEM CAPABLE OF VERIFYING LOADING STATE

(71) Applicant: ATECO INC., Gunpo-si (KR)

(72) Inventors: Taek Seon Lee, Hwaseong-si (KR); Ho Nam Kim, Seongnam-si (KR); Sung Chul Moon, Gunpo-si (KR)

(21) Appl. No.: 19/643,222

(22) Filed: Apr. 9, 2026

(30) Foreign Application Priority Data
Apr. 23, 2025 (KR) 10-2025-0053277
Mar. 10, 2026 (KR) 10-2026-0043234

(51) Int. Cl. G01R 31/28

(52) U.S. Cl. CPC G01R 31/2893

(57) ABSTRACT

Disclosed is a test device transport system capable of verifying a loading state, including: a tray on which a test device is loaded in a horizontal posture; a picker configured to load the test device on the tray; and a loading state verifier configured to verify a loading state of the test device based on a difference in posture between a normal state, in which the test device is loaded on the tray in the horizontal posture, and an abnormal state, in which the test device is loaded in a posture other than the horizontal posture.

### CROSS REFERENCE TO RELATED APPLICATIONS

Priority to Korean Patent Application No. 10-2025- 0053277 filed on Apr. 23, 2025, and Korean Patent Application No. 10-2026-0043234 filed on Mar. 10, 2026, the entire disclosures of which are incorporated by reference herein, is claimed.

### BACKGROUND OF THE DISCLOSURE

### Field of the Disclosure

The disclosure relates to a test device transport system capable of verifying a loading state. More particularly, the disclosure relates to a transport system which is disposed between a handler configured to receive test devices to be tested and to discharge tested test devices, and a tester configured to perform a mounting test on the test devices, and transports the test devices between the handler and the tester.

### Description of the related Art

Among recently developed memory modules, some have a configuration in which a plurality of dynamic random access memory (DRAMs) are mounted on a board. An example of a memory module known to have a plurality of DRAMs mounted on a board as described above is a small outline compression attached memory module (SOCAMM). To achieve high power efficiency and bandwidth, various components, including DRAMs, are mounted on the surface of such a memory module. Furthermore, recently, there has been a trend toward forming memory modules in the smallest possible size by minimizing a redundant area where no components are mounted, so as to minimize the space occupied by the memory module in an installed state.

However, such a trend toward miniaturization and integration of memory modules has maximized efficiency in terms of use but has presented another challenge in performing a mounting test of the memory modules.

Specifically, before being supplied to the actual market, a memory module is mounted on a test apparatus having a motherboard to evaluate its performance. Such a test is referred to as a so-called mounting test because the memory module is tested in an actually mounted state. In this case, to maximize the efficiency of the mounting test, a system that automatically performs the mounting test while transporting the memory module is essential. However, the aforementioned trend toward the miniaturization and integration of memory modules implies a decrease in regions of the memory module with which an automated apparatus can be in direct contact. Therefore, a new type of test apparatus and method capable of handling recently developed memory modules in large quantities is required.

### SUMMARY OF THE DISCLOSURE

An aspect of the disclosure is to provide a new transport system capable of stably transporting test devices such that a mounting test can be automated even for the test devices recently developed to have a reduced contact area.

Another aspect of the disclosure is to provide a transport system for transporting test devices in a horizontal posture to stably support the test devices.

Still another aspect of the disclosure is to provide a transport system capable of verifying a loading state of test devices loaded in a horizontal posture.

The aspects of the disclosure are not limited to the aspects mentioned above, and other objects not mentioned will be readily understood by those skilled in the art from the description below.

According to an embodiment of the disclosure, a test device transport system capable of verifying a loading state includes: a tray on which a test device is loaded in a horizontal posture; a picker configured to load the test device on the tray; and a loading state verifier configured to verify a loading state of the test device based on a difference in posture between a normal state, in which the test device is loaded on the tray in the horizontal posture, and an abnormal state, in which the test device is loaded in a posture other than the horizontal posture.

The loading state verifier may include a camera configured to photograph the test device loaded on the tray from above.

The loading state verifier may further include an image processor configured to verify the loading state of the test device based on a verification image captured by the camera.

The tray may include a pair of fixing members positioned on both sides of the test device loaded on the tray so as to hold the test device.

The image processor may be configured to verify the loading state of the test device, using a difference in shape between the fixing members shown in the verification image based on a difference in posture of the test device between the normal state and the abnormal state.

The image processor may verify that the test device is in the normal state when terminal portions of the pair of fixing members are photographed as overlapping the test device in the verification image.

The image processor may verify the loading state of the test device based on a shape of a contour of the test device shown in the verification image.

The plurality of test devices may be loaded on the tray, and the loading state verifier may include the plurality of cameras. The plurality of cameras may be installed above a transport path along which the tray is moved. Each position of the plurality of cameras may be set to distributively photograph the plurality of test devices loaded on the tray while the tray is being transported along the transport path.

The loading state verifier may include a distance measurement sensor connected to the picker and configured to measure a distance to a surface of the test device positioned below the picker.

The loading state verifier may further include a distance information processor configured to verify the loading state of the test device using distance information measured by the distance measurement sensor.

The distance measurement sensor may include: a first distance measurement sensor configured to measure a distance to a first point on the test device; and a second distance measurement sensor configured to measure a distance to a second point different from the first point on the test device.

The distance information processor may verify that the test device is in the abnormal state when a difference between the distance measured by the first distance measurement sensor and the distance measured by the second distance measurement sensor exceeds a preset range.

The first distance measurement sensor and the second distance measurement sensor may be located at positions symmetrical with respect to the picker.

The distance measurement sensor may be set to measure a distance to a surface of the test device when the picker moves up by a predetermined height after placing the test device on the tray.

Other details of the disclosure are included in the detailed description and the accompanying drawings.

### BRIEF DESCRIPTION OF THE DRAWINGS

FIG. 1 is a diagram conceptually illustrating a test system including a transport system according to an embodiment of the disclosure.

FIG. 2 is a view conceptually illustrating a test device to be transported in a transport system according to an embodiment of the disclosure.

FIG. 3 is a view conceptually illustrating a side of a test device on which a contact portion is formed.

FIG. 4 is a view conceptually illustrating a test device laid in a horizontal posture, viewed laterally.

FIG. 5 is a view illustrating a test tray according to an embodiment of the disclosure.

FIG. 6 is a view illustrating an insert according to an embodiment of the disclosure.

FIG. 7 is a block diagram of a loading state verifier according to a first embodiment of the disclosure.

FIG. 8 is a view illustrating a state in which a test device loaded on a test tray is photographed by the loading state verifier according to the first embodiment of the disclosure.

FIG. 9 is a view illustrating an insert viewed from a position of a camera disposed according to an embodiment of the disclosure.

FIG. 10 is a view briefly illustrating a state in which a test device is fixed to a fixing member in a normal state according to an embodiment of the disclosure.

FIG. 11 is a view illustrating the fixing member on the left viewed from above in the state illustrated in FIG. 10.

FIG. 12 is a view briefly illustrating a state in which a test device is fixed to a fixing member in an abnormal state according to an embodiment of the disclosure.

FIG. 13 is a view illustrating the fixing member on the left viewed from above in the state illustrated in FIG. 12.

FIG. 14 is a block diagram of a loading state verifier according to a second embodiment of the disclosure.

FIG. 15 is a view illustrating a picker and a distance measurement sensor installed on the picker according to an embodiment of the disclosure.

FIG. 16 is a view schematically illustrating a state in which a picker loads a test device onto a tray according to an embodiment of the disclosure.

FIG. 17 is an enlarged view of an area AA of FIG. 16.

FIG. 18 is a view illustrating a state in which a picker is aligned above an insert to load a test device according to an embodiment of the disclosure.

FIG. 19 is a view illustrating a state in which the picker of FIG. 18 moves down to load the test device into the insert.

FIG. 20 is a view illustrating a state that the picker of FIG. 19 moves up by a predetermined height after placing the test device.

### DETAILED DESCRIPTION OF THE DISCLOSURE

Advantages and features of the disclosure and methods for achieving them will become apparent with reference to the embodiments described in detail below together with the accompanying drawings. However, the disclosure is not limited to the embodiments disclosed below, but may be implemented in various different forms. These embodiments are merely provided to make the disclosure complete and to fully inform those skilled in the art, to which the disclosure pertains, of the scope of the disclosure, and the disclosure is only defined by the scope of the claims.

In addition, the embodiments described in this specification will be described with reference to cross-sectional views and/or schematic views, which are idealized illustrations of the disclosure. Therefore, the forms of the illustrations may be modified by manufacturing techniques and/or tolerances. In addition, in each drawing shown in the disclosure, each component may be somewhat enlarged or reduced for convenience of description. Like reference numerals refer to like components throughout the specification.

Descriptions related to directions such as up, down, front, rear, left, or right mentioned below are merely provided based on the states shown in the accompanying drawings to facilitate a clear understanding of the disclosure. Therefore, the disclosure is not limited to the directions mentioned below. That is, at the time of actual use or installation of the disclosure, the disclosure may be used or installed in directions different from the directions mentioned below, and the disclosure should be interpreted as including such modified embodiments.

In addition, a “test device” referred to below may be a semiconductor product in the form of a module or a card packaged at a second level.

In addition, a “tray” referred to below is a collective term for a “test tray” and a “user tray.” The test tray is designed to be mounted on a tester with test devices loaded thereon. In a state where the test tray is mounted on the tester, the test devices loaded on the test tray are electrically connected to the sockets of the tester. Meanwhile, the user tray is formed to store the test devices in an arrangement according to user convenience. Test devices to be tested are supplied to the test system while being loaded on the user tray. Similarly, the test devices for which testing is completed are loaded back onto the user tray and then discharged from the test system.

Hereinafter, the disclosure will be described with reference to the drawings for explaining a test device transport system capable of verifying a loading state according to an embodiment of the disclosure.

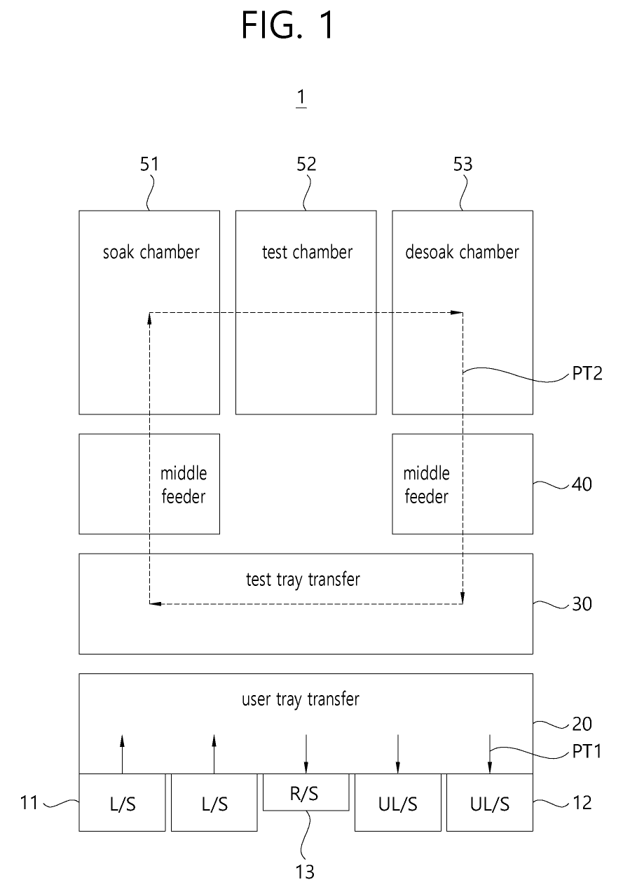

FIG. 1 is a diagram conceptually illustrating a test system including a transport system according to an embodiment of the disclosure.

As shown in FIG. 1, a test system 1 including a transport system according to an embodiment of the disclosure includes a plurality of stackers 11, 12, 13, a plurality of transfers 20, 30, a plurality of middle feeders 40, and a plurality of chambers 51, 52, 53.

In this case, the transport system may be defined as a set of components that transport trays along a user tray transport path PT1 and a test tray transport path PT2 (to be described later), or transport test devices between the user tray transport path PT1 and the test tray transport path PT2, inside the test system 1

The plurality of stackers 11, 12, 13, the plurality of transfers 20, 30, and pickers installed in corresponding regions may be components for implementing a conventionally known handler. In this case, a picker refers to a device configured to pick up and place test devices.

First, the plurality of stackers 11, 12, 13 may be classified into a loading stacker 11, an unloading stacker 12, and a reject stacker 13 according to their installation purposes. The specific number of each stacker 11, 12, 13 may be vary depending on the specifications of the test system 1. Commonly, the plurality of stackers 11, 12, 13 are structured to stack a plurality of user trays. In addition, each of the plurality of stackers 11, 12, 13 is configured to exchange a user tray with a user tray transfer 20. In this case, since the tray exchange structure between the stacker and the transfer is widely known in the related art, a detailed description thereof will be omitted.

A user tray loaded with test devices requiring testing is stored in the loading stacker 11. The user tray may be stored in the loading stacker 11 by a robot, an automated guided vehicle (AGV), and/or manual operation of an operator. A user tray loaded with test devices that have been tested is stored in the unloading stacker 12. Similarly, the user tray stored in the unloading stacker 12 may be discharged from the unloading stacker 12 by the robot, the AGV, and/or the manual operation of an operator. The reject stacker 13 stores a user tray loaded with defective test devices. The test devices stored in the reject stacker 13 are subsequently discharged and discarded.

The user tray transfer 20 may be designed to exchange user trays with the loading stacker 11 and the unloading stacker 12 in units of one lot. In this case, a lot refers to a supply unit of user trays set in consideration of an optimized working environment. That is, a lot refers to a unit for counting the number of user trays transported at one time. In this case, one lot of user trays may be transported between the user tray transfer 20 and the loading/unloading stackers 11, 12 in a stacked state.

Meanwhile, the user tray transfer 20 may be configured to discharge user trays loaded with defective products to the reject stacker 13 as needed. This is because the number of test devices evaluated as defective products is substantially very small compared to that of good products.

Therefore, a user tray transport path PT1 is mainly formed between each of the stackers 11, 12, 13 and the user tray transfer 20 as shown in FIG. 1.

Meanwhile, the user tray transfer 20 may have a gripper and a set plate. The gripper is configured to place a user tray transferred from the loading stacker 11 on the set plate, or to retrieve a user tray placed on the set plate and transport it to another set plate or a location within the user tray transfer 20 for discharging the user tray to the unloading stacker 12 or the reject stacker 13.

Meanwhile, the set plates may be provided one by one in front of each of the stackers 11, 12, 13. In addition, the set plate may be configured to move up and down. In a state where the set plate moves up to its maximum height, an exchange of test devices is performed between a user tray placed on the set plate and a test tray positioned on the test tray transfer 30. In this case, the exchange of the test devices is performed by a picker.

Specifically, a user tray transferred from the loading stacker 11 is placed on a set plate positioned in front of the loading stacker 11. When the picker transfers all test devices loaded on the user tray to the test tray, the gripper transfers the empty user tray to a set plate positioned in front of the reject stacker 13 or the unloading stacker 12.

A user tray placed on a set plate positioned in front of the reject stacker 13 or the unloading stacker 12 receives test devices from a test tray that has completed testing. This operation is likewise performed by a picker. When the user tray is fully loaded, the set plate moves down to a height at which the gripper can pick up the user tray. When the downward movement of the set plate is completed, the gripper retrieves the user tray from the set plate to transfer the user tray to a corresponding stacker.

Similar to the user tray transfer 20, the test tray transfer 30 may include a gripper and a plurality of set plates. In the test tray transfer 30 as well, the set plates are configured to move up and down, and the gripper is configured to transport a test tray between different set plates.

The set plates installed in the test tray transfer 30 may correspond to the set plates installed in the user tray transfer 20 on a one-to-one basis. More particularly, the set plates installed in the test tray transfer 30 may be installed one by one in front of the set plates installed in the user tray transfer 20, respectively. The set plates installed in the test tray transfer 30 and the set plates installed in the user tray transfer 20 may be positioned at the same or similar heights at their maximum heights. In a state where the set plates installed in the test tray transfer 30 and the set plates installed in the user tray transfer 20 are moved upward to their maximum heights, the exchange of test devices between the test tray and the user tray is performed. That is, after the test tray and the user tray are moved upward along the set plates while being placed on the set plates, the test devices are discharged or loaded by the picker.

Specifically, in front of the loading stacker 11, test devices loaded on a user tray are transported to a test tray. Conversely, in front of the reject stacker 13 and the unloading stacker 12, test devices loaded on a test tray are transported to a user tray. An empty test tray, from which all test devices have been collected in front of the reject stacker 13 and the unloading stacker 12, is picked up by a gripper and transferred to a set plate positioned in front of the loading stacker 11.

The middle feeder 40 is configured to move the test tray along a linear path. For example, the middle feeder 40 may be configured to move the test tray along a linear path using various conventionally known driving devices such as a conveyor or a robot hand. One middle feeder 40 may be installed between a soak chamber 51 and the test tray transfer 30, and another middle feeder 40 may be installed between a desoak chamber 53 and the test tray transfer 30, respectively.

The middle feeder 40 installed between the soak chamber 51 and the test tray transfer 30 retrieves a test tray prepared at the set plate and transfers it to the soak chamber 51. Hereinafter, the area between the soak chamber 51 and the test tray transfer 30 is referred to as a chamber loading area.

On the other hand, the middle feeder 40 installed between the desoak chamber 53 and the test tray transfer 30 retrieves a test tray, which has been cooled in the desoak chamber, and transfers it to the test tray transfer 30. Hereinafter, an area between the desoak chamber 53 and the test tray transfer 30 is referred to as a chamber unloading area.

The soak chamber 51 refers to a chamber for slowly preheating a test tray in preparation for the environment of the test chamber 52. In contrast, the desoak chamber 53 is a chamber where the test tray is slowly cooled to match an external temperature before being discharged to the outside. Meanwhile, the test chamber 52 has an internal temperature set to a temperature required for a mounting test and includes a tester on which the test tray is mounted. The tester has a plurality of sockets electrically connected to each test device in a state of being in close contact with the test tray. The tester evaluates the function of the test device by exchanging electrical signals with the test device through the sockets.

Movement of the test tray among the soak chamber 51, the test chamber 52, and the desoak chamber 53 may be implemented by using various conventionally known configurations. As an example, in the corresponding area, the test tray may be moved by being towed by a holder moving along an actuator. Here, the holder may refer to a member configured to hold the test tray.

Summarizing the above description from the perspective of a test tray transport path PT2, a test tray initially waits in an empty state on a set plate positioned in front of the loading stacker 11. Thereafter, when a user tray is loaded, a picker operates to collect new test devices from the user tray and transport them to the empty test tray. When the test tray is fully loaded, the middle feeder 40 operates to transfer the test tray to the soak chamber 51. Subsequently, the test tray sequentially moves through the soak chamber 51, the test chamber 52, and the desoak chamber 53, and sequentially undergoes preheating, testing, and heat-removal processes. When cooling is completed in the desoak chamber 53, the test tray is transferred back to the test tray transfer 30 by the middle feeder 40. When the test tray is loaded onto a set plate positioned in front of the unloading stacker 12, the picker retrieves the test devices from the test tray and transports them to the user tray. When the picker retrieves all the test devices from the test tray, the empty test tray is moved back to the set plate positioned in front of the loading stacker. This process may be repeated until all test devices requiring testing are transferred to the tester.

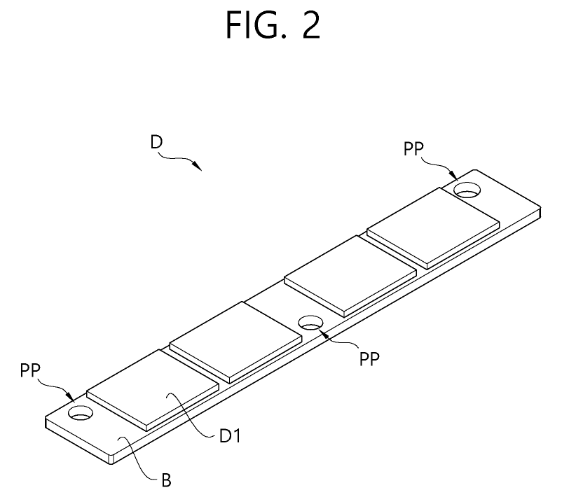

Hereinafter, a test device to be transported by a transport system according to an embodiment of the disclosure will be described with reference to FIGS. 2-4.

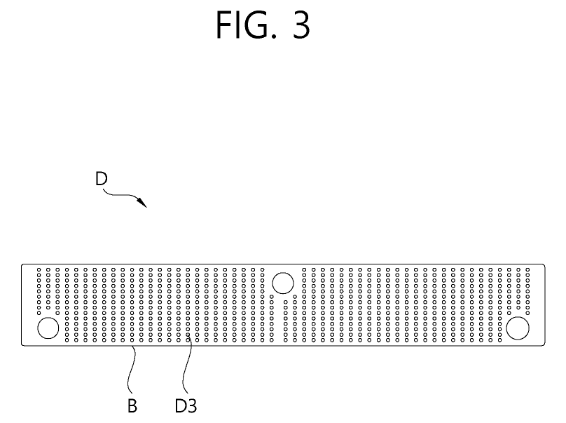

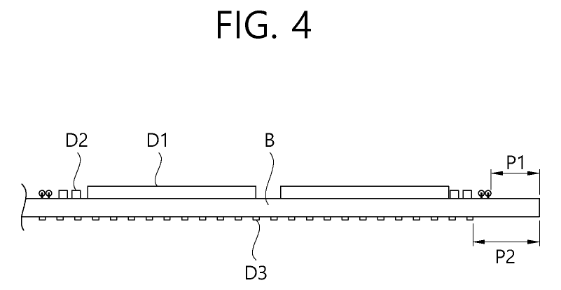

FIG. 2 is a view conceptually illustrating a test device to be transported by a transport system according to an embodiment of the disclosure. In this regard, FIG. 3 is a view conceptually illustrating a side of a test device on which a contact portion is formed. In addition, FIG. 4 is a view conceptually illustrating a test device laid in a horizontal posture, viewed laterally.

Referring to FIGS. 2, 3, and 4, a test device D tested according to the disclosure may be formed with a board B, which has a shape substantially similar to a thin plate, as a basic framework. Components installed in the test device D may be positioned on one side of the board B, and terminals D3 may be formed on the opposite side of the board B. In this case, the components installed on the side of the test device D include a semiconductor chip D1 and an element D2. Also, in this case, the terminal D3 may be an end portion of a signal path electrically connected to the semiconductor chip D1 and/or the element D2.

As an example, the test device D may be a SO-CAMM or a similar memory module, and the semiconductor chip D1 may be a memory chip. More specifically, the semiconductor chip D1 may be a DRAM or another similar RAM. In addition, for example, the element D2 may be various elements required for a memory module, including active elements such as various transistors and diodes and/or passive elements such as inductors, resistors, and capacitors. The terminal D3 may be formed as a type of means used for electrical contact known in the related art, such as a TSV or a BGA. During a mounting test, the terminal D3 is used as a contact portion electrically connected to a socket of a tester.

In the test device D, a portion where the semiconductor chip D1 to the elements D2 are installed corresponds to a portion that is difficult for automation apparatus to contact and handle. This is because the semiconductor chip D1 to the element D2 may be damaged when the automation apparatus transfers or supports the test device D by touching such a portion. For convenience of description, hereinafter, a portion on the board B where the semiconductor chip D1 to the elements D2 are installed and thus is difficult for apparatus to contact is referred to as a non-contactable portion, and a portion where the semiconductor chip D1 to the elements D2 are absent and thus is easily contactable is referred to as a contactable portion.

As shown in FIGS. 2 and 3, when a hole is formed through the board B, a through portion PP surrounding the hole generally corresponds to a contactable portion since the semiconductor chip D1 or the element D2 is absent therein. In addition, referring to FIGS. 2 and 4, both end portions of the board B generally correspond to contactable portions since the semiconductor chip D1 or the element D2 is absent therein. In this case, due to the intensive installation of the semiconductor chips D1 and the elements D2, an allowance space P2 at both ends of the side of the board B where the terminals D3 are installed is wider than an allowance space P1 at both ends of the side where the semiconductor chips D1 and the elements D2 are installed.

Considering the structural characteristics of the test device D as described above, in the case of transporting the test device D in a standing posture, a method of fixing the test device D by holding a small contactable portion at both ends of the test device D may be considered. However, as the allowance spaces P1 and P2 (especially the P1 portion) existing at both ends of the test device D become increasingly narrow, it is becoming increasingly difficult to appropriately fix the test device D in such a manner. In particular, depending on manufacturing tolerances, there are test devices D in which the allowance spaces P1 and P2 are narrower than designed, and in such a case, there is a higher possibility that the test device D cannot be appropriately fixed to the apparatus.

In this case, the disclosure proposes a transport system capable of loading and transporting the test device D in a horizontal posture, focusing on a characteristic in which the allowance space P2 of the portion where the terminals D3 are installed is wider than the allowance space P1 on the opposite side.

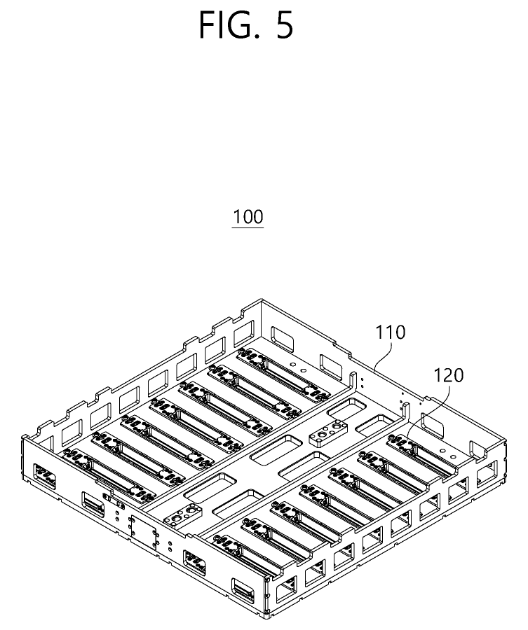

Based on the foregoing description, a test tray used as a type of tray in a transport system according to an embodiment of the disclosure will be described below. FIG. 5 is a view illustrating a test tray according to an embodiment of the disclosure.

As shown in FIG. 5, a test tray 100 according to an embodiment of the disclosure is provided in a form in which a plurality of inserts 120 are mounted on a tray body 110.

The tray body 110 is formed in a shape capable of being placed on a tester. For example, the tray body 110 may be provided in a form in which a plurality of recesses (hereinafter, mounting recesses) are formed through a bottom surface of a box-shaped member having a substantially open top surface. In this case, each mounting recess is formed to correspond to a position of each socket formed on an upper surface of the tester. Here, the mounting recess refers to a recess into which the insert 120 is inserted. The mounting recess may be formed to have a cross-section slightly larger than that of the insert 120. The insert 120 is capable of moving due to a clearance with the mounting recess in a state of being mounted on the tray body 110.

The inserts 120 are each formed to load one test device. In this case, the insert 120 is configured to load the test device in a horizontal posture. Here, the horizontal posture refers to a posture in which the test device is laid down such that its height is minimized. Meanwhile, although the example in FIG. 5 illustrates the inserts 120 being mounted on the tray body 110 in 2 rows and 8 columns, the test tray 100 according to the disclosure is not necessarily limited to the embodiment shown in FIG. 5. That is, the number of inserts 120 mounted on the tray body 110 may be changed as much as desired according to the number of sockets of the tester.

On the other hand, although not shown, the user tray is also configured to load test devices in a horizontal posture, similar to the test tray 100. However, since the user tray is not configured for the purpose of being mounted on a tester, it is sufficient if it is configured to simply load the test devices in a horizontal posture while omitting the inserts 120 and mounting recesses.

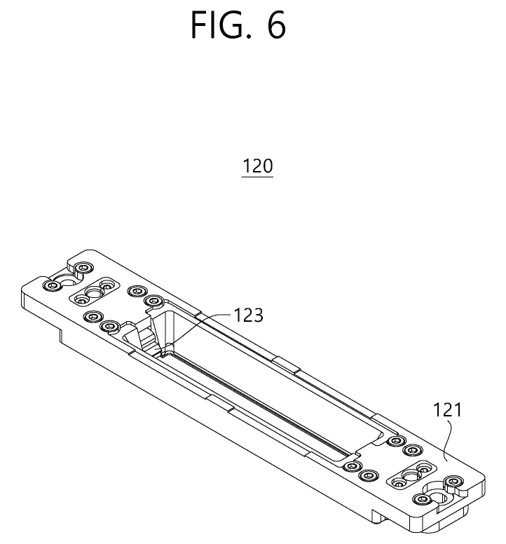

Hereinafter, the insert 120 according to an embodiment of the disclosure will be described with reference to FIG. 6. FIG. 6 is a view illustrating an insert according to an embodiment of the disclosure. As shown in FIG. 6, the insert 120 according to an embodiment of the disclosure includes an insert body 121 and a fixing member 123.

The insert body 121 is provided in a shape that can be inserted and mounted into a mounting recess of the test tray. Additionally, a loading space in which a test device in a horizontal posture is loaded is formed in a central portion of the insert body 121. In this case, the loading space is open at the bottom. This is to allow the sockets and the test device to contact each other while the test tray is placed on the tester.

A pair of fixing members 123 are disposed to face each other with the loading space of the insert body 121 at the center. Furthermore, each fixing member 123 is connected to the insert body 121 so as to be capable of reciprocating. An elastic member may be disposed between each fixing member 123 and the insert body 121 such that the fixing member 123 protrudes toward the loading space as much as possible in the absence of an external force. As an example, the elastic member may be provided as a type of conventionally widely known spring, such as a coil spring. When a test device is placed inside the loading space, the pair of fixing members 123 press the test device from both sides to fix the test device inside the loading space.

In this case, in order to switch the pair of fixing members 123 to an open state during the process of placing the test device inside the loading space, the picker may include an opener for opening the fixing members. For example, the opener may be configured to open the pair of fixing members 123 by including a pair of inclined surfaces that press the pair of fixing members in directions in which the fixing members move away from each other while the picker moves down.

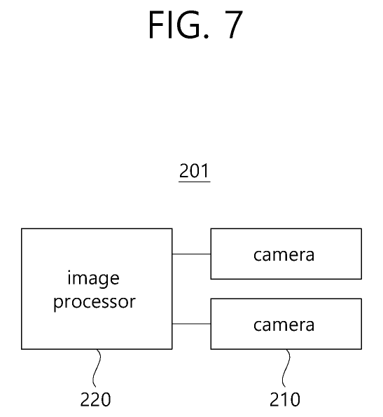

Hereinafter, a loading state verifier 201 according to a first embodiment, which may be included in the transport system according to an embodiment of the disclosure, will be described with reference to FIGS. 7-13. First, FIG. 7 is a block diagram of a loading state verifier according to a first embodiment of the disclosure.

The loading state verifier 201 verifies a loading state of a test device based on a difference in posture between a normal state and an abnormal state of the test device. In this case, the normal state is a state in which the test device is loaded in an insert in a horizontal posture, and the abnormal state is a state in which the test device is loaded in the insert in a posture other than the horizontal posture.

Referring to FIG. 7, the loading state verifier 201 may include a plurality of cameras 210 and an image processor 220. In this case, although FIG. 7 illustrates an example in which two cameras 210 are included in the loading state verifier 201, the number of cameras 210 may be variously changed in consideration of a shape of the test tray and the processing performance of the image processor 220.

Each camera 210 may be installed to photograph a corresponding one of the inserts. For example, the camera 210 may be installed above the middle feeder 40 (see FIG. 1) located in the chamber loading area to photograph a test tray being transferred to the soak chamber 51 (see FIG. 1) by the middle feeder 40. Accordingly, each camera 210 photographs the corresponding insert and the test device loaded therein from above while the test tray is moving. Hereinafter, an image captured by the camera 210 is referred to as a verification image.

The image processor 220 is configured to verify a loading state of a test device using the verification image. For example, the image processor 220 may be provided as an algorithm configured to perform such a task, a program including such an algorithm, a recording medium in which such an algorithm or program is non-transitorily recorded, or an information processing device configured to execute such an algorithm or program. A detailed method by which the image processor 220 verifies the loading state of the test device using the verification image will be described later.

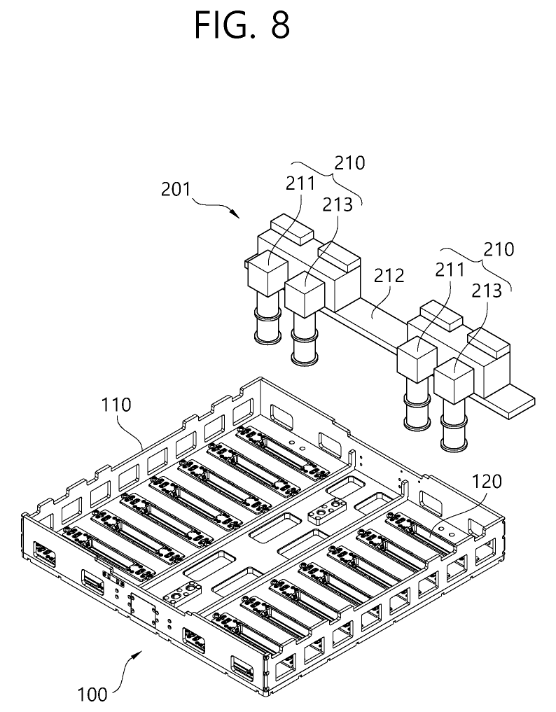

Hereinafter, an installation form of the loading state verifier 201 will be described with reference to FIG. 8. FIG. 8 is a view illustrating a state in which a test device loaded on a test tray is photographed by the loading state verifier according to the first embodiment of the disclosure.

Referring to FIG. 8, the loading state verifier 201 includes an installation frame 212 that supports the plurality of cameras 210 on a movement path of the test tray 100. The installation frame 212 may be provided as a substantially linear plate-shaped member fixed to a space above the middle feeder.

The number of cameras 210 is provided to correspond to the number of columns of the inserts 120 mounted on the test tray 100. For example, in FIG. 8, the inserts 120 of the test tray 100 are arranged in two columns, and correspondingly, two cameras 210 are provided. In this case, the test tray 100 is moved along a direction parallel to the columns of the inserts 120. For convenience of description, a path along which the test tray is transported is hereinafter referred to as a transport path.

Each camera 210 is installed to be positioned above one column of the inserts 120 moving along the transport path. Therefore, one column of the inserts 120 passes through a space below the camera 210 in charge of the corresponding column while moving along the transport path. While the test tray 100 passes through the transport path, each camera 210 sequentially photographs the inserts 120 of the column in its charge. That is, the cameras 210 distributively photograph the test devices loaded on the test tray 100 for each column.

Specifically, the camera 210 may include a first camera 211 and a second camera 213. The first camera 211 and the second camera 213 are installed to photograph different areas of a single insert 120, and are configured to transfer the captured verification images to the image processor through a wired or wireless manner. In addition, the first camera 211 and the second camera 213 may each be fixed to the installation frame 212 so as to face the insert 120 passing below.

The positions of the first camera 211 and the second camera 213 may be set to photograph different fixing members in the insert located below each camera. That is, the first camera 211 and the second camera 213 may distributively photograph a pair of fixing members of a single insert. To this end, the first camera 211 is installed to be positioned directly above a fixing member located on one side from above the insert 120 moving along the transport path. In contrast, the second camera 213 is installed to be positioned directly above a fixing member located on the other side. Each of the first camera 211 and the second camera 213 may be focused on the fixing member passing below.

Meanwhile, the first camera 211 and the second camera 213 may be set to capture verification images at each preset photographing time point in accordance with the movement time of the test tray 100. In this case, the interval between the photographing time points may be set to the time required for the next insert 120 to reach the lower portions of the first camera 211 and the second camera 213 after the verification image of the previous insert 120 was captured.

Alternatively, the first camera 211 and the second camera 213 may be configured to photograph the insert 120 according to a control signal from a controller. As an example, the controller may be set to transfer a control signal to the first camera 211 and the second camera 213 whenever a sensor installed to recognize the insert detects the insert. As another example, the controller may transfer a control signal to the first camera 211 and the second camera 213 according to a user’s operation.

In the foregoing example, the description is based on an example including the first camera 211 and the second camera 213, but the disclosure is not necessarily limited to such an embodiment. For example, the camera 210 may be configured to photograph the test device and the insert 120 as a whole using a single camera. However, for convenience of description, the following will be described based on an embodiment including the first camera 211 and the second camera 213.

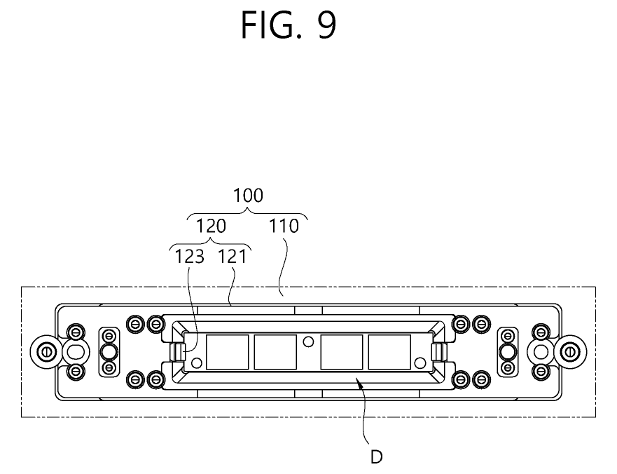

Continuing the description with reference to FIG. 9, FIG. 9 is a view illustrating an insert viewed from a position of a camera disposed according to an embodiment of the disclosure. As shown in FIG. 9, the test device D passing below the camera is positioned between a pair of fixing members 123. In this state, the test device D is aligned with a central portion of the insert body 121.

If the test device D is fixed by the fixing member (123) in a normal state, the contact portion of the test device D and the socket are aligned and brought into contact with each other when the insert body (121) is subsequently placed on the tester. Conversely, if the test device D is in an abnormal state, the contact portion of the test device D may be misaligned with the socket or tilted in one direction when the insert body (121) is placed on the tester, making it difficult to perform the test on the test device D. Therefore, to ensure the reliability of the test, it is necessary to identify the test device D in an abnormal state before transferring it to the tester.

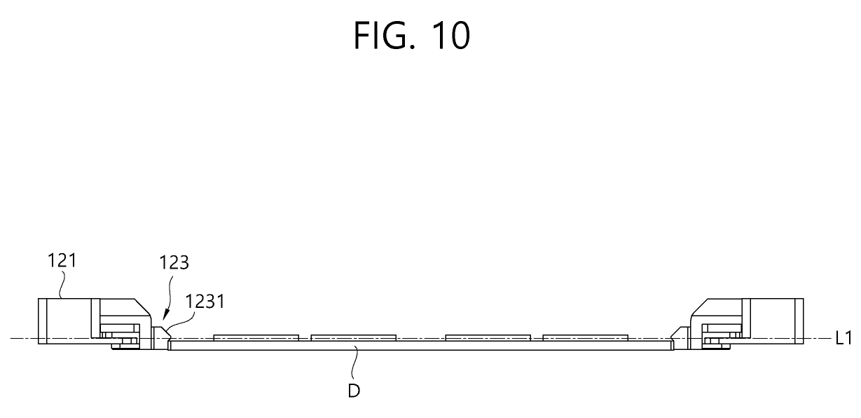

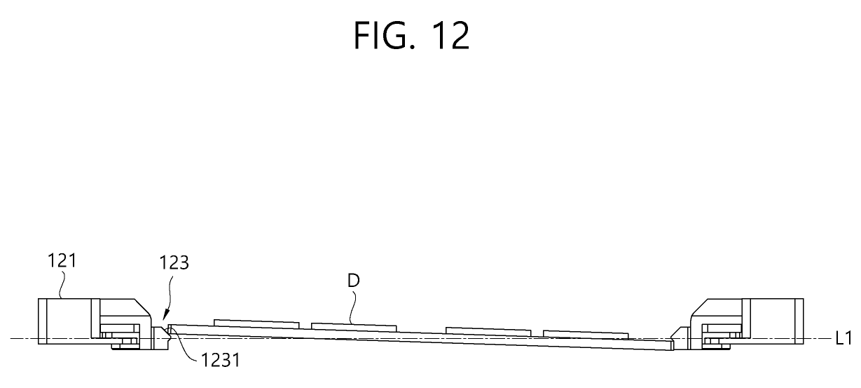

Hereinafter, with reference to FIGS. 10-13, differences in shapes appearing on verification images due to the difference in posture of the test device between a normal state and an abnormal state will be described. In this case, to clearly illustrate the fixing member (123) and the test device D, only the portion of the insert body (121) directly coupled to the fixing member (123) is shown in FIGS. 10 and 12, and the illustration of the remaining portions is omitted.

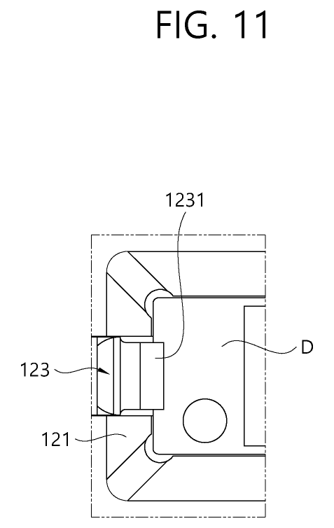

First, the normal state will be described with reference to FIGS. 10 and 11. FIG. 10 is a view briefly illustrating a state in which a test device is fixed to a fixing member in a normal state according to an embodiment of the disclosure. In this regard, FIG. 11 is a view illustrating the fixing member on the left viewed from above in the state illustrated in FIG. 10.

Referring to FIGS. 10 and 11, a test device D fixed in a normal posture has a posture parallel to a straight line L1 extending across terminal portions 1231 of a pair of facing fixing members 123. Specifically, a long side of the test device D becomes parallel to the straight line L1. In addition, in the normal state, the lower portions of the terminal portions 1231 of the pair of fixing members 123 are in close contact with the side surfaces of the test device D. The pair of terminal portions 1231 press the test device D toward each other from opposite sides to fix the position of the test device D.

In this case, the upper portion of the terminal portion 1231 protrudes toward the opposite fixing member from the upper side of the lower portion that is in close contact with the side surface. Due to this shape, the upper portion of the terminal portion 1231 overlaps the upper surface of the test device D fixed in the normal state. Therefore, in a verification image captured by photographing the test device D loaded in the normal state, a shape in which the terminal portion 1231 covers the upper surface of the test device D is verified.

Accordingly, the image processor verifies that the test device D is in the normal state when the terminal portion 1231 of the fixing member 123 is photographed as overlapping the test device D on the captured verification image. A method by which the image processor verifies whether the terminal portion 1231 overlaps the upper surface of the test device D may be implemented by utilizing various conventionally known image analysis techniques.

For example, the image processor may be configured to distinguish between the fixing member 123 and the test device D using an algorithm trained to detect objects on a verification image, and to determine whether the fixing member 123 is positioned above the test device D.

As another example, the image processor may be configured to distinguish between the fixing member 123 and the test device D based on preset RGB pixel values and to extract the contours of the fixing member 123 and the test device D to determine whether the fixing member 123 is positioned above the test device D. For instance, the image processor may determine that the fixing member 123 is positioned above the test device D when a short side of the test device D in the identified contour bends along the contour of the terminal portion 1231.

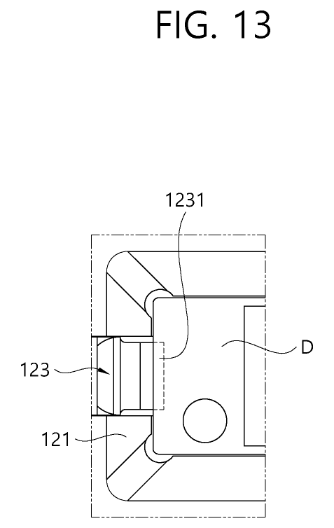

The abnormal state will be described below with reference to FIGS. 12 and 13. FIG. 12 is a view briefly illustrating a state in which a test device is fixed to the fixing member in an abnormal state according to an embodiment of the disclosure. In this regard, FIG. 13 is a view illustrating the fixing member on the left viewed from above in the state illustrated in FIG. 12.

Referring to FIGS. 12 and 13, the test device D fixed in an abnormal posture may have a posture that intersects a straight line L1 extending across the terminal portions 1231 of a pair of facing fixing members 123. Specifically, the test device D in the abnormal state may be tilted such that its long side intersects the straight line L1.

In the abnormal state, due to the tilt of the test device D, only the fixing member 123 on one side (hereinafter, a normal contact side) is in close contact with the side surface of the test device D, while the fixing member 123 on the other side (hereinafter, an abnormal contact side) may fail to be in close contact with the side surface of the test device D. Due to this tilt, the test device D is placed above the terminal portion 1231 of the fixing member 123 on the abnormal contact side. Therefore, in a verification image captured by photographing the test device D in the abnormal state, the terminal portion 1231 of the fixing member 123 on the abnormal contact side is hidden by the test device D and is not visible.

Accordingly, the image processor determines that the test device D is in the abnormal state if the test device D detected on the verification image is identified as being positioned above the fixing member 123. For example, as described above, the image processor may identify the arrangement state of the test device D and the fixing member 123 by detecting objects in the verification image, or may verify whether the test device D is positioned above the fixing member 123 based on the contour shape of a short side of the test device D. In the case of verifying the arrangement state using the contour shape of the short side, if the contour of the short side of the test device D is identified as a straight line, the image processor determines that the test device D is in the abnormal state.

If the test device D is verified to be in an abnormal state, the image processor outputs an alert signal and transfers it to the middle feeder or a controller that controls the middle feeder. Upon receiving the alert signal, the middle feeder may stop its operation and wait without transferring the test tray to the soak chamber. Thereafter, the system may be restarted after a user or a separate automation device retrieves the test tray or corrects the abnormal test device D to a proper posture.

In the above description, the example in which the image processor verifies the normal and abnormal states by identifying the vertical arrangement of the test device D and the terminal portion 1231 was used as a basis, but the disclosure is not necessarily limited to such an embodiment. For example, the image processor may verify the loading state of the test device based on the shape of the overall contour of the test device shown in the verification image.

Specifically, as described above, a major difference between the normal state and the abnormal state of the test device D lies in the tilt of the test device D. Therefore, when viewed from above, the test device D in the normal state has a generally rectangular contour, whereas the test device D in the abnormal state has a generally trapezoidal contour. Utilizing this, the image processor may identify the contour of the long side of the test device D from the verification image and then distinguish between the normal and abnormal states according to the extracted contour shape of the long side. Specifically, the image processor may verify that the test device D is in the normal state if the contour of the long side of the test device D is parallel to the straight line L1 or the central axis of the insert extending along the width direction, and verify it as an abnormal state if it is not parallel.

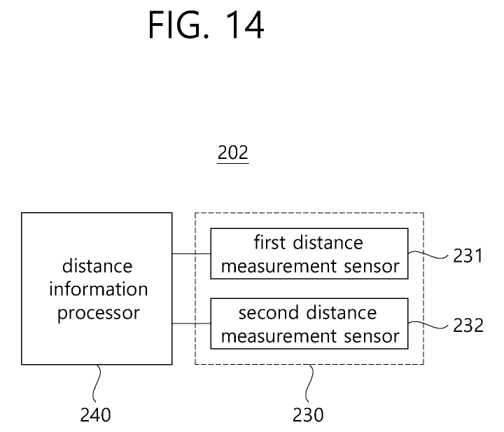

Based on the above description, a loading state verifier 202 according to a second embodiment of the disclosure will be described below with reference to FIGS. 14-20. In this case, the loading state verifier according to the first embodiment and the loading state verifier according to the second embodiment are not in an exclusive relationship requiring that only one of them be selected and installed in a single transport system. That is, a single transport system may include both the loading state verifier according to the first embodiment and the loading state verifier according to the second embodiment.

Continuing the description with reference to FIG. 14, FIG. 14 is a block diagram of a loading state verifier according to a second embodiment of the disclosure. As shown in FIG. 14, the loading state verifier 202 according to the second embodiment may include a distance measurement sensor 230 and a distance information processor 240.

The distance information processor 240 is configured to verify a loading state of a test device using distance information measured by the distance measurement sensor 230. For example, the distance information processor 240 may be provided as an algorithm configured to perform such a task, a program including such an algorithm, a recording medium in which such an algorithm or program is non-transitorily recorded, or an information processing device configured to execute such an algorithm or program. A detailed method by which the distance information processor 240 verifies the loading state of the test device using the distance information will be described later.

The distance measurement sensor 230 is connected to a picker that picks up a test device, and is configured to measure the distance to a surface of the test device positioned below the picker. For example, the distance measurement sensor 230 may be configured by utilizing various conventionally known distance measurement sensors capable of measuring a distance in a non-contact manner. For example, the distance measurement sensor 230 may be configured using an infrared distance measurement sensor, a laser distance measurement sensor, an ultrasonic distance measurement sensor, or the like. Upon receiving a control signal from a controller, the distance measurement sensor 230 measures the distance to the surface of the test device and is configured to transfer the measured distance information to the distance information processor 240 using wired or wireless communication.

Meanwhile, the distance measurement sensor 230 may include a first distance measurement sensor 231 configured to measure the distance to a first point on the test device, and a second distance measurement sensor 232 configured to measure the distance to a second point different from the first point on the test device. For example, the first distance measurement sensor 231 and the second distance measurement sensor 232 may be installed at different positions to measure distances to different points.

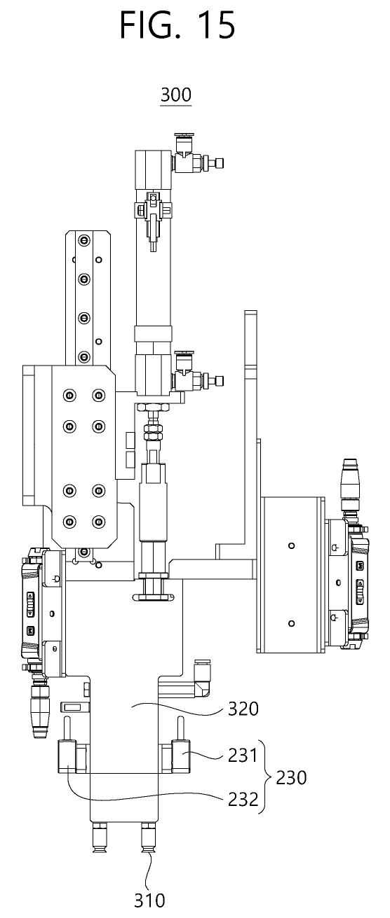

Hereinafter, an installation example of the distance measurement sensor 230 will be described with reference to FIG. 15. FIG. 15 is a view illustrating a picker and a distance measurement sensor installed on the picker according to an embodiment of the disclosure.

Referring to FIG. 15, the picker 300 may include a picker body 320 forming an overall framework, and a plurality of suction modules 310 installed at a lower end of the picker body 320. Each suction module 310 is configured to pick up an object using negative pressure. The plurality of suction modules 310 may be arranged at predetermined intervals along a width direction of the picker body 320 on a bottom surface of the picker body 320.

As an example, the suction module 310 may include a substantially cylindrical body and a suction pad connected to a lower end of the body and formed of an elastic material. In this case, a suction flow path for transferring negative pressure generated from an external negative pressure source may be formed through the body along a central axis. In contrast, the suction pad may have a ring shape connected to a bottom surface of the body around the suction flow path. Additionally, the suction pad may extend downward in a radial direction, such that its overall shape is similar to an inverted cup.

When negative pressure is applied to the suction flow path while the suction module 310 is in close contact with a test device, the suction pad is deformed due to a pressure difference between the inside and outside of the body, thereby adhering to the test device. Thereafter, when the picker body 320 moves, the test device moves together with the suction module 310 while being held in close contact therebetween by the negative pressure transferred through the body.

Meanwhile, the first distance measurement sensor 231 and the second distance measurement sensor 232 may be connected to different sides of the picker body 320, respectively, with the picker body 320 interposed therebetween. That is, the first distance measurement sensor 231 and the second distance measurement sensor 232 may be mounted on opposite sides of the picker body 320 in a width direction, respectively. Additionally, the first distance measurement sensor 231 and the second distance measurement sensor 232 may be configured to measure a distance to an object located below them.

In this case, the width of the picker body 320 may be smaller than the width of the test device. Therefore, when the test device is picked up, the test device may be exposed to both sides of the picker body 320. The first distance measurement sensor 231 and the second distance measurement sensor 232 may measure the distances to portions of the test device exposed on both sides of the picker body 320. Such positioning of the first distance measurement sensor 231 and the second distance measurement sensor 232 may be intended to maximize a difference between the distances measured by the first distance measurement sensor 231 and the second distance measurement sensor 232 when the test device is tilted.

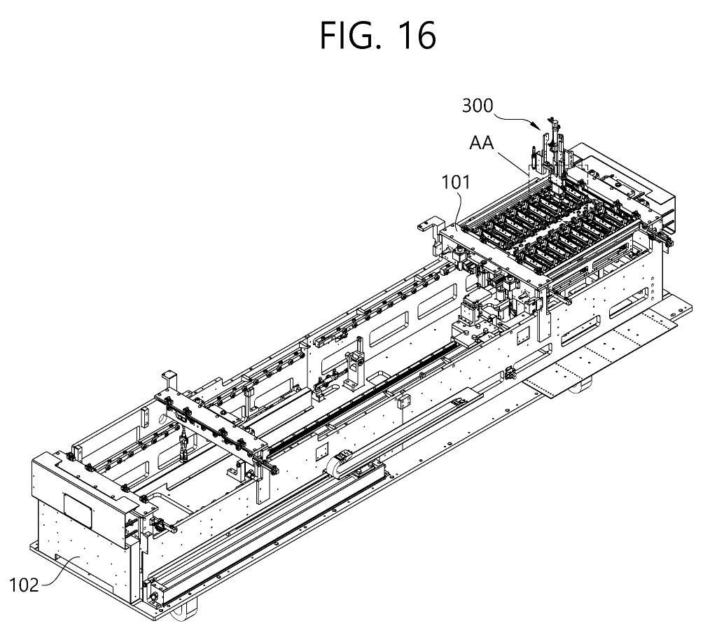

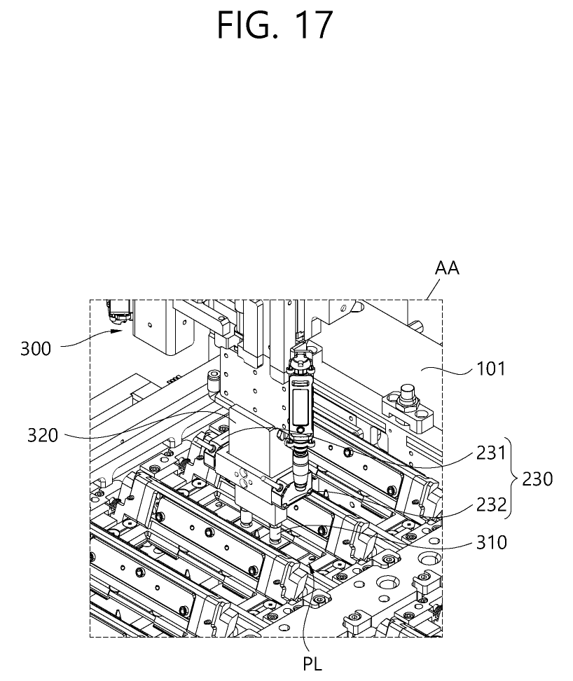

Hereinafter, a usage example of the loading state verifier according to the second embodiment will be described with reference to FIGS. 16 and 17. FIG. 16 is a view schematically illustrating a state in which a picker loads a test device onto a tray according to an embodiment of the disclosure. In this regard, FIG. 17 is an enlarged view of an area AA of FIG. 16.

The tray 101 shown in FIG. 16 may be either a user tray or a test tray. In addition, depending on the type of the tray 101, the transfer 102 may be referred to as a test tray transfer or a user tray transfer.

Referring to FIGS. 16 and 17, the picker 300 may place test devices at each loading position PL on the tray 101. In this case, although FIG. 16 illustrates a cover (without a reference numeral) coupled to the tray 101 to cover the test device seated at the loading position PL, the cover may be omitted.

For example, if the tray 101 is a test tray, the loading position PL may correspond to an interior of the insert. In this case, the picker 300 may pick up a test device to be tested from the user tray and load it into the loading position PL of the tray 101, i.e., the test tray.

As another example, if the tray 101 is a user tray, the loading position PL may be an interior of a recess formed in the user tray to receive the test device. In this case, the picker 300 may pick up the test device for which testing has been completed from the test tray and load it into the loading position PL of the tray 101, i.e., the user tray.

Meanwhile, the first distance measurement sensor 231 and the second distance measurement sensor 232 may be configured to measure the distance to the test device when the picker 300 moves up by a predetermined height after placing the test device at the loading position PL. For example, the predetermined height may be set by a user through prior experimentation. The upward movement of the picker 300 may be implemented by setting a time for the picker 300 to move up after the negative pressure of the suction module 310 is removed. When the negative pressure of the suction module 310 is removed, the picker body 320 moves up in a vertical direction relative to the loading position PL. In this process, the suction module 310, from which the negative pressure has been removed, and the test device are separated.

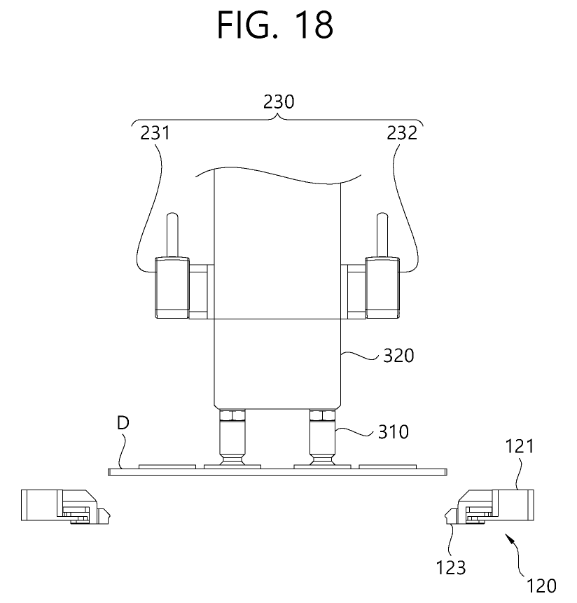

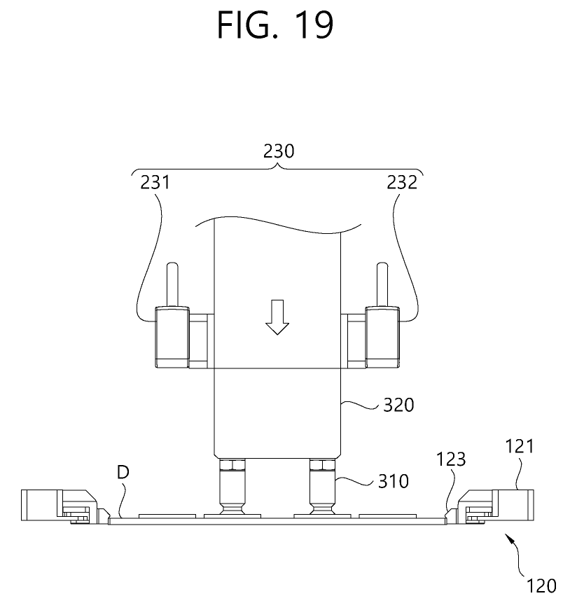

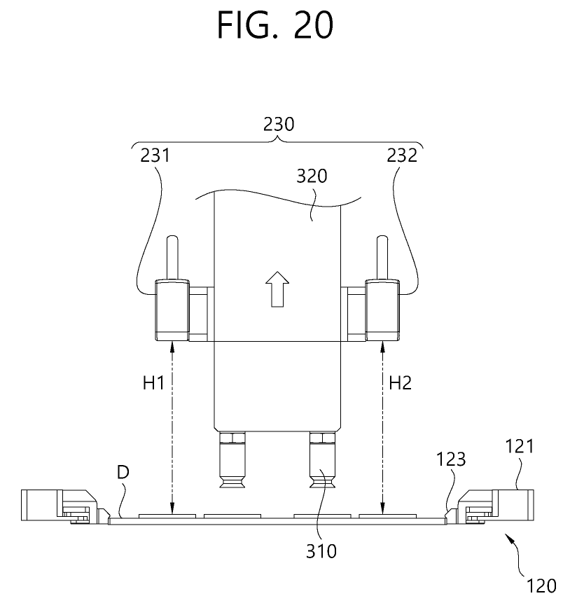

Hereinafter, a method of verifying the loading state of a test device using the distance measurement sensor 230 will be described with reference to FIGS. 18 and 20. FIG. 18 is a view illustrating a state in which a picker is aligned above an insert to load a test device according to an embodiment of the disclosure. In this regard, FIG. 19 is a view illustrating a state in which the picker of FIG. 18 moves down to load the test device into the insert. Finally, FIG. 20 is a view illustrating a state that the picker of FIG. 19 moves up by a predetermined height after placing the test device.

In this case, FIGS. 18 and 20 illustrate the process of loading the test device D into the insert 120 of the test tray, but the placement of the test device D may proceed similarly for a user tray as well. Additionally, in FIGS. 18 and 20, as in FIGS. 10 and 12, only the portions of the insert body 121 directly coupled to the fixing members 123 are shown, and the illustration of the remaining portions is omitted to clearly represent the fixing members 123 and the test device D.

Referring to FIG. 18, first, the picker 300, after picking up the test device D, is aligned with a position at which the central axis of the picker body 320 and the central axis of the insert body 121 are coaxial. In this state, the test device D is aligned in the vertical direction with the space formed between the pair of fixing members 123.

Thereafter, as shown in FIG. 19, when the picker body 320 moves down, the pair of fixing members 123 are moved apart in opposite directions, and the test device D enters between the fixing members 123. Specifically, the test device D contacts the terminal portions 1231 (see FIGS. 10 and 12) during the downward movement process. In this case, due to the inclined shape of the upper ends of the terminal portions 1231, the pressing force applied by the test device D acts on the fixing members 123 in a direction toward the insert body 121. As a result, the pair of fixing members 123 overcome the elastic force of the elastic members and move toward the insert body 121. In this state, the pair of fixing members 123 press the test device D from both sides by the restoring force of the elastic members.

Referring to FIG. 20, after completing the placement of the test device D, the picker 300 moves up again by a predetermined height. In this state, the first distance measurement sensor 231 and the second distance measurement sensor 232 measure the distances to the test device D, respectively. Specifically, the first distance measurement sensor 231 measures a distance H1 to the test device D located directly below it, and the second distance measurement sensor 232 measures a distance H2 to the test device D located directly below it.

Thereafter, the distance information processor compares the distance H1 measured by the first distance measurement sensor 231 with the distance H2 measured by the second distance measurement sensor 232. If the difference between the measured distances H1 and H2 exceeds a preset range, the distance information processor verifies that the test device D is in an abnormal state. In this case, the preset range is set in advance considering the design tolerance of the test device D.

Specifically, referring to FIGS. 10 and 12, in a normal state, since the test device D is substantially parallel to the straight line L1, the difference between the distance H1 measured by the first distance measurement sensor 231 and the distance H2 measured by the second distance measurement sensor 232 is expected to be within a range identical or similar to the design tolerance range of the test device D. Therefore, if the difference between the distance H1 measured by the first distance measurement sensor 231 and the distance H2 measured by the second distance measurement sensor 232 exceeds the preset range, it can be determined that the test device D is tilted as shown in FIG. 12. Since the first distance measurement sensor 231 and the second distance measurement sensor 232 measure the distances to both ends of the test device D, even a minute tilt can be identified by maximizing the difference between the measured distances H1 and H2.

In the above description, the explanation was based on an embodiment in which the distance measurement sensor 230 measures the distance after the picker 300 has moved up by a predetermined height following the placement of the test device D; however, the disclosure is not necessarily limited to such an embodiment.

For example, the distance measurement sensor 230 may be configured to measure the distance simultaneously with the suction module 310 removing the negative pressure. Alternatively, the distance measurement sensor 230 may be configured to measure the distance in a state where the picker 300 has moved down as shown in FIG. 19, even if the negative pressure has not yet been removed.

Meanwhile, although FIGS. 18-20 illustrate an example in which both the first distance measurement sensor 231 and the second distance measurement sensor 232 measure the distance to a memory chip, the disclosure is not necessarily limited to such an example. For example, at least one of the first distance measurement sensor 231 and the second distance measurement sensor 232 may be installed to measure a distance to a board portion.

According to embodiments of the disclosure, at least the following effects are achieved.

Even test devices with a small contact area can be stably transported, thereby improving the automation efficiency of a mounting test.

Abnormally loaded test devices can be promptly identified, thereby shortening system downtime caused by improper loading.

The effects according to the disclosure are not limited to the contents exemplified above, and various other effects are also encompassed within the present specification.

A person having ordinary skill in the art to which the disclosure pertains will understand that the disclosure may be implemented in other specific forms without changing its technical spirit or essential features. Therefore, it should be understood that the embodiments described above are illustrative in all respects and not restrictive. The scope of the disclosure should be defined by the appended claims rather than the foregoing description, and all changes or modifications derived from the meaning, scope, and equivalents of the appended claims should be construed as being included in the scope of the disclosure.

### REFERENCE NUMERALS

1: test system
11: loading stacker
12: unloading stacker
13: reject stacker
20: user tray transfer
30: test tray transfer
40: middle feeder
51: soak chamber
52: test chamber
53: desoak chamber
100: test tray 1
101: tray
102: transfer
110: tray body
120: insert
121: insert body
123: fixing member
201, 202: loading state verifier
210: camera
211: first camera
212: installation frame
213: second camera
220: image processor
230: distance measurement sensor
231: first distance measurement sensor
232: second distance measurement sensor
240: distance information processor
300: picker
310: suction module
320: picker body

What is claimed is:

1. A test device transport system capable of verifying a loading state, the test device transport system comprising:
a tray on which a test device is loaded in a horizontal posture;
a picker configured to load the test device on the tray; and
a loading state verifier configured to verify a loading state of the test device based on a difference in posture between a normal state, in which the test device is loaded on the tray in the horizontal posture, and an abnormal state, in which the test device is loaded in a posture other than the horizontal posture.

2. The test device transport system of claim 1, wherein the loading state verifier comprises a camera configured to photograph the test device loaded on the tray from above.

3. The test device transport system of claim 1, wherein the loading state verifier further comprises an image processor configured to verify the loading state of the test device based on a verification image captured by the camera.

4. The test device transport system of claim 3, wherein
the tray comprises a pair of fixing members positioned on both sides of the test device loaded on the tray so as to hold the test device, and
the image processor is configured to verify the loading state of the test device, using a difference in shape between the fixing members shown in the verification image based on a difference in posture of the test device between the normal state and the abnormal state.

5. The test device transport system of claim 4, wherein the image processor verifies that the test device is in the normal state upon terminal portions of the pair of fixing members being photographed as overlapping the test device in the verification image.

6. The test device transport system of claim 3, wherein the image processor verifies the loading state of the test device based on a shape of a contour of the test device shown in the verification image.

7. The test device transport system of claim 1, wherein
a plurality of test devices are loaded on the tray,
the loading state verifier comprises a plurality of cameras,
the plurality of cameras are installed above a transport path along which the tray is moved, and
each position of the plurality of cameras is set to distributively photograph the plurality of test devices loaded on the tray while the tray is being transported along the transport path.

8. The test device transport system of claim 1, wherein the loading state verifier comprises a distance measurement sensor connected to the picker and configured to measure a distance to a surface of the test device positioned below the picker.

9. The test device transport system of claim 8, wherein the loading state verifier further includes a distance information processor configured to verify the loading state of the test device using distance information measured by the distance measurement sensor.

10. The test device transport system of claim 9, wherein the distance measurement sensor comprises:
a first distance measurement sensor configured to measure a distance to a first point on the test device; and
a second distance measurement sensor configured to measure a distance to a second point different from the first point on the test device.

11. The test device transport system of claim 10, wherein the distance information processor verifies that the test device is in the abnormal state upon a difference between the distance measured by the first distance measurement sensor and the distance measured by the second distance measurement sensor exceeding a preset range.

12. The test device transport system of claim 10, wherein the first distance measurement sensor and the second distance measurement sensor are located at positions symmetrical with respect to the picker.

13. The test device transport system of claim 8, wherein the distance measurement sensor is set to measure a distance to a surface of the test device upon the picker moving up by a predetermined height after placing the test device on the tray.
